(19) United States
(12) Patent Application Publication
(10) Pub. No.: US 2021/0313364 A1
(43) Pub. Date: Oct. 7, 2021

(54) ARRAY SUBSTRATE AND DISPLAY PANEL

(71) Applicant: Wuhan China Star Optoelectronics Technology Co., Ltd, Wuhan, Hubei (CN)

(72) Inventors: Zhifu LI, Wuhan, Hubei (CN); Juncheng Xiao, Wuhan, Hubei (CN); Fei Al, Wuhan, Hubei (CN); Jiyue Song, Wuhan, Hubei (CN)

(21) Appl. No.: 16/955,112

(22) PCT Filed: Apr. 17, 2020
(86) PCT No.: PCT/CN2020/085265

§ 371 Date: Jun. 18, 2020

(30) Foreign Application Priority Data
Apr. 7, 2020 (CN) 202010263559.9

(51) Int. Cl. H01L 27/146; G02F 1/1333; G02F 1/1368; G02F 1/133; G06F 3/041; G06K 9/00

(52) U.S. Cl. CPC H01L 27/14612; H01L 27/14603; G02F 1/13338; G02F 1/136227; G02F 1/13312; G06F 3/0412; G06K 9/0004; G02F 1/13685

(57) ABSTRACT

The present disclosure provides an array substrate and a display panel. The array substrate includes a substrate, a thin film transistor layer, and a fingerprint identification component. Through horizontally disposing a switching element and a fingerprint identification element of the fingerprint identification component in the thin film transistor layer, the fingerprint identification element and the switching element can be manufactured with the thin film transistor layer at a same time, which can reduce a thickness of the panel, and a structure thereof is simple and not complicated.

### FIELD OF INVENTION

The present disclosure relates to the field of display technologies, and more particularly, to an array substrate and a display panel.

### BACKGROUND OF INVENTION

Fingerprint identification technology has been widely applied in small-size and medium-size panels, and it mainly includes capacitive, ultrasonic, and optical methods. Compared to capacitive and ultrasonic fingerprint identification technologies, optical fingerprint identification has good stability, strong antistatic ability, good penetration ability, and lower cost. Optical fingerprint identification technology uses a principle of light refraction and reflection. When light irradiates a finger, it is reflected by the finger and is received by a photosensitive sensor. After receiving the light, the photosensitive sensor can convert an optical signal into an electrical signal for reading. Because valleys and ridges of a fingerprint reflect light differently, intensities of reflected light received by the sensor from the valleys and ridges are different, and magnitude of converted currents or voltages thereof is also different. Therefore, special points in the fingerprint can be captured to provide unique confirmation information. However, due to restrictions such as aperture ratios and backlights, current mobile phones with under-display fingerprint identification function that can be seen in the market are mainly equipped with organic light-emitting diode (OLED) screens. Various manufacturers are working hard to develop liquid crystal display (LCD) mobile phones with in-display fingerprint identification function.

Technical problem: for optical fingerprint identification technology, photosensitive sensors are a key module that realizes conversion of optical signals into electrical signals that can be directly read. Integrating the photosensitive sensors into interiors of screens to achieve full-screen fingerprint identification can greatly improve users' experiences, but processes of integrated array substrates will become complicated.

Therefore, it is necessary to provide a new array substrate to reduce a thickness of the panel.

### SUMMARY OF INVENTION

An objective of the present disclosure is to provide an array substrate and a display panel. Through horizontally disposing a switching element and a fingerprint identification element of a fingerprint identification component in a thin film transistor layer, the fingerprint identification element and the switching element can be manufactured with the thin film transistor layer at a same time, which can reduce a thickness of the panel, and a structure thereof is simple and not complicated.

To achieve the above objective, an embodiment of the present disclosure provides an array substrate which comprises: a substrate; a thin film transistor layer disposed on the substrate; and a fingerprint identification component disposed in the thin film transistor layer; wherein the fingerprint identification component comprises a switching element and a fingerprint identification element, and the switching element and the fingerprint identification element are adjacently disposed on the substrate; and the switching element comprises a first semiconductor, the fingerprint identification element comprises a second semiconductor, and the first semiconductor and the second semiconductor are manufactured on a same layer.

Further, the thin film transistor layer comprises: a semiconductor layer disposed on the substrate, wherein the first semiconductor and the second semiconductor are disposed in the semiconductor layer; a gate insulating layer disposed on the semiconductor layer; a gate electrode disposed on the gate insulating layer and corresponding to the first semiconductor; an interlayer insulating layer disposed on the gate insulating layer and the gate electrode; a first metal layer disposed on the interlayer insulating layer and connected to the semiconductor layer by at least one via hole, wherein the via hole penetrates through the interlayer insulating layer and the gate insulating layer until a surface of the semiconductor layer; and a planarization layer disposed on the first metal layer and the interlayer insulating layer.

Further, one end of the first semiconductor is directly connected to one end of the second semiconductor.

Further, the second semiconductor comprises a first N₊doped region and a first P+ doped region, and a first gap is defined between the first N+ doped region and the first P+ doped region.

Further, a second gap is defined between the first semiconductor and the second semiconductor; and the first metal layer has a connecting line, one end of the connecting line is connected to the first semiconductor, and another end of the connecting line is connected to the second semiconductor.

Further, the second semiconductor further comprises a first active region disposed between the first N+ doped region and the first P+ doped region; and the first metal layer has a first metal line connected to the first P+ doped region by the via hole.

Further, the array substrate also comprises a photosensitive layer disposed on the second semiconductor, and a material of the photosensitive layer is amorphous silicon.

Further, the array substrate also comprises: an insulating layer disposed between the substrate and the thin film transistor layer; a light shielding layer disposed in the insulating layer; a first electrode layer disposed on the thin film transistor layer; a touch control insulating layer disposed on a first electrode layer and provided with a slot recessed to a surface of the first electrode layer; and a storage capacitor layer disposed on the touch control insulating layer and in the slot, and connected to the first metal layer; wherein, the Storage capacitor layer includes a display area storage capacitor and a fingerprint identification storage capacitor, and the display area storage capacitor is connected to the first electrode layer through the slot.

Further, the storage capacitor layer comprises: a first transparent electrode layer disposed on the touch control insulating layer; wherein the first transparent electrode layer in the display area storage capacitor area is connected to the first electrode layer through the slot, and the first transparent electrode layer in the fingerprint identification storage capacitor area is connected to the fingerprint identification element; a passivation layer disposed on the first transparent electrode layer and the touch control insulating layer; and a second transparent electrode layer disposed on the passivation layer, wherein the second transparent electrode layer in the display area storage capacitor area is connected to the switching element.

An embodiment of the present disclosure further provides a display panel which comprises the above array substrate, a liquid crystal layer disposed on the array substrate; and a color filter substrate disposed on the liquid crystal layer.

Beneficial effect: the present disclosure provides an array substrate and a display panel. Through horizontally disposing a switching element and a fingerprint identification element of a fingerprint identification component in a thin film transistor layer, the fingerprint identification element and the switching element can be manufactured with the thin film transistor layer at a same time, which can reduce a thickness of the panel, and a structure thereof is simple and not complicated. Specifically, when manufacturing the first semiconductor and the second semiconductor, doped regions can also be manufactured at a same time by introducing phosphine and borane gases after patterning corresponding patterns, so that an additional process for introducing gases is unnecessary, thereby saving cost. In addition, compared to conventional LTPS processes, the present disclosure only needs to add masks for manufacturing the first P+ doped region and the photosensitive layer, thereby having lower production cost.

### DESCRIPTION OF DRAWINGS

FIG. 1 is a schematic structural diagram of an array substrate according to an embodiment of the present disclosure.

FIG. 2 is a schematic structural diagram of an array substrate according to an embodiment of the present disclosure.

FIG. 3 is an equivalent circuit diagram of a fingerprint identification component according to an embodiment of the present disclosure.

FIG. 4 is a schematic structural diagram of a display panel according to an embodiment of the present disclosure.

FIG. 5 is a schematic structural diagram of an array substrate according to another embodiment of the present disclosure.

### DETAILED DESCRIPTION OF PREFERRED EMBODIMENTS

The present disclosure provides an array substrate and a display panel. In order to make the purpose, technical solutions, and effects of this disclosure clearer and more definite, the following further describes this disclosure in detail with reference to the drawings and embodiments. It should be understood that the specific embodiments described herein are only used to explain the disclosure, and are not used to limit the disclosure.

The present disclosure provides an array substrate which comprises a substrate, a thin film transistor layer, and a fingerprint identification component.

The thin film transistor layer is disposed on the substrate, and the fingerprint identification component is disposed in the thin film transistor layer.

Wherein, the fingerprint identification component comprises a switching element and a fingerprint identification element, and the switching element and the fingerprint identification element are adjacently disposed on the substrate; and the switching element comprises a first semiconductor, the fingerprint identification element comprises a second semiconductor, and the first semiconductor and the second semiconductor are manufactured on a same layer.

The present disclosure does not limit a number of fingerprint identification components. In actual manufacturing, an array substrate is composed of a plurality of fingerprint identification components. For better explanation, the present disclosure draws a set of fingerprint identification component in the drawings to better describe the embodiments.

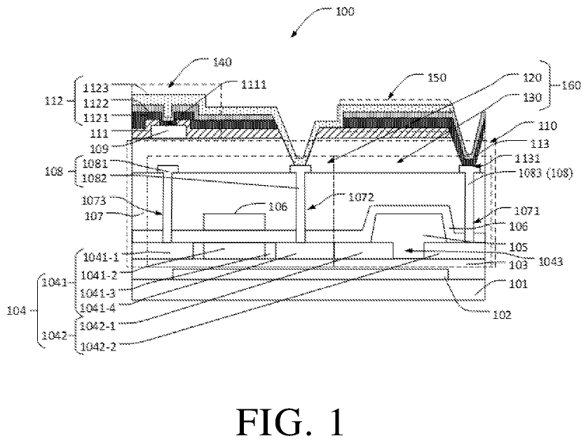

As shown in FIG. 1, an array substrate 100 provided in an embodiment of the present disclosure comprises a substrate 101, an insulating layer 103, a thin film transistor layer 110, a fingerprint identification component 160, a first electrode layer 109, a touch control insulating layer 111, and a storage capacitor layer 112.

The insulating layer 103 is provided with a light shielding layer 102 disposed on the substrate 101 for reducing an aperture ratio.

The light shielding layer 102 is obtained by patterning using an exposure and etching method.

The thin film transistor layer 110 is disposed on the substrate 101, and the fingerprint identification component 160 is disposed in the thin film transistor layer 110.

The fingerprint identification component 160 comprises a switching element 120 and a fingerprint identification element 130, and the switching element 120 and the fingerprint identification element 130 are adjacently disposed on the substrate 101. A structure of the switching element 120 is same as a structure of a thin film transistor device.

Embodiment 1 of the present disclosure horizontally disposes the switching element 120 and the fingerprint identification element 130 of the fingerprint identification component 160 in the thin film transistor layer 110. The fingerprint identification element 130 and the switching element 120 can be manufactured with the thin film transistor layer 120 at a same time, so that it is not necessary to spend a lot of cost to manufacture the fingerprint identification element 130.

The switching element 120 comprises a first semiconductor 1041, the fingerprint identification element 130 comprises a second semiconductor 1042, and the first semiconductor 1041 and the second semiconductor 1042 are manufactured on a same layer.

The thin film transistor layer 110 includes a semiconductor layer 104, a gate insulating layer 105, a gate electrode 106, an interlayer insulating layer 107, a first metal layer 108, and a planarization layer 113.

The semiconductor layer 104 is disposed on the substrate 101, and the first semiconductor 1041 and the second semiconductor 1042 are disposed in the semiconductor layer 104.

The first semiconductor 1041 comprises a second N+ doped region 1041-4, a third N+ doped region 1041-1, and a second active region 1041-2 disposed between the second N+doped region 1041-4 and the third N+ doped region 1041-1.

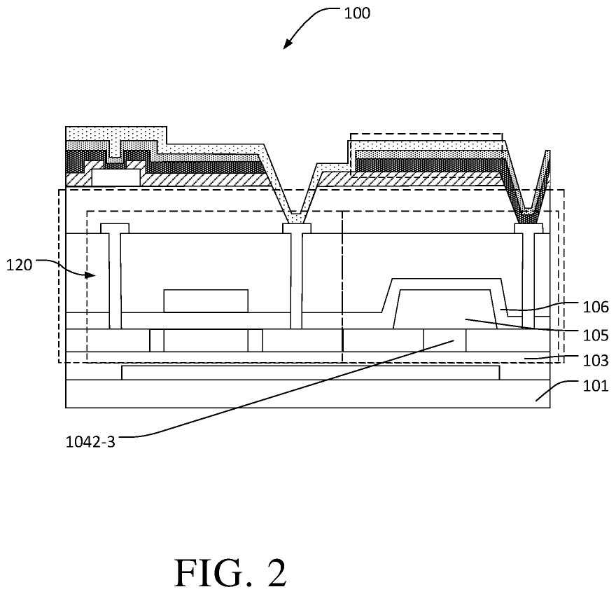

The second semiconductor 1042 comprises a first N+ doped region 1042-1 and a first P+ doped region 1042-2, and a first gap 1043 is defined between the first N+ doped region 1042-1 and the first P+ doped region 1042-2. In other embodiments, the second semiconductor 1042 further comprises a first active region 1042-3 disposed between the first N+ doped region 1042-1 and the first P+ doped region 1042-2, that is, disposed in the first gap 1043 (as shown in FIG. 2).

One end of the first semiconductor 1041 is directly connected to one end of the second semiconductor 1042. Specifically, the second N+ doped region 1041-4 and the first N+ doped region 1042-1 are directly connected, and it is not necessary to separate the first semiconductor 1041 and the second semiconductor 1042.

Specifically, when manufacturing the first semiconductor 1041 and the second semiconductor 1042, corresponding patterns are patterned, and then the doped regions can also be manufactured at a same time by introducing phosphine and borane gases, so that an additional process for introducing gases is unnecessary.

A material of the second active region 1041-2 is low temperature polysilicon, and the second N+ doped region 1041-4 and the third N+doped region 1041-1 are doped with phosphorus ions in the semiconductor layer 104.

A photosensitive layer is disposed on the second semiconductor 1042, and the photosensitive layer further enhances light absorption effect of the fingerprint identification element 130. A material of the photosensitive layer is amorphous silicon, and the photosensitive layer is patterned and formed by exposure and etching.

The gate insulating layer 105 is disposed on the semiconductor layer 104. The gate electrode 106 is disposed on the gate insulating layer 105 and corresponds to the first semiconductor 1041. Specifically, the gate electrode 106 corresponds to the second active region 1041-2. Then, with help of the gate electrode 106 as a blocking layer, implantation of N-ions can be performed on two ends of the second active region 1041-2, thereby forming N-doped regions 1041-3 at the two ends of the second active region 1041-2.

The interlayer insulating layer 107 is disposed on the gate insulating layer 105 and the gate electrode 106. The interlayer insulating layer 107 adopts a stacked structure of silicon nitride and silicon oxide. In addition, rapid thermal annealing is used to perform hydrogenation and activation, which allows metal silicide to quickly deposit, so that the interlayer insulating layer 107, semiconductor layer 104, and the photosensitive layer can be quickly deposited chemically.

The first metal layer 108 is disposed on the interlayer insulating layer 107 and is connected to the semiconductor layer 104 by via holes penetrating through the interlayer insulating layer 107 and the gate insulating layer 105 until a surface of the semiconductor layer 104.

The first metal layer 108 has a second metal line, and the first semiconductor 1041 and the second semiconductor 1042 are respectively connected to the second metal line.

The via holes include a first via hole 1071, a second via hole 1072, and a third via hole 1073.

The second metal line includes a source electrode wire 1081 and a drain electrode wire 1082, and the drain electrode wire 1082 and the source electrode wire 1081 are connected to the second N+ doped region 1041-4 and the third N+ doped region 1041-1 through the second via hole 1072 and the third via hole 1073, respectively.

The first metal layer 108 further has a first metal line 1083, and the first metal line 1083 is connected to the first P+ doped region 1042-2 through the first via hole 1071.

The planarization layer 113 is disposed on the first metal layer 108 and the interlayer insulating layer 107. The first electrode layer 109 is disposed on the thin film transistor layer 110, and the first electrode layer 109 is a touch control electrode layer.

The touch control insulating layer 111 is disposed on the first electrode layer 109 and is provided with a slot 1111 recessed to a surface of the first electrode layer 109.

The storage capacitor layer 112 is disposed on the touch control insulating layer 111 and in the slot 1111, and is connected to the first metal layer 108 through at least one groove 1131. The grooves 1131 are formed in the planarization layer 113, and the first metal layer 108 is exposed in the grooves 1131.

The storage capacitor layer 112 includes a display area storage capacitor and a fingerprint identification storage capacitor. The display area storage capacitor is connected to the source electrode wire 1081 or the drain electrode wire 1082 through the grooves 1131, that is, the display area storage capacitor is connected to the switching element 120. The display area storage capacitor is connected to the first electrode layer 109 through the slot 1111.

The fingerprint identification storage capacitor is connected to the first metal line 1083 through the grooves 1131, that is, connected to the fingerprint identification element 130.

The storage capacitor layer 112 includes a first transparent electrode layer 1121, a passivation layer 1122, and a second transparent electrode layer 1123.

The first transparent electrode layer 1121 is a common electrode layer and is disposed on the touch control insulating layer 111. The first transparent electrode layer 1121 in a display area storage capacitor area is connected to the first electrode layer 109 through the slot 1111. The first transparent electrode layer 1121 in a fingerprint identification storage capacitor area is connected to the first metal line 1083 through the grooves 1131, that is, connected to the fingerprint identification element 130.

The passivation layer 1122 is disposed on the first transparent electrode layer 1121 and the touch control insulating layer 111.

The second transparent electrode layer 1123 is a pixel electrode layer and is disposed on the passivation layer 1122. The second transparent electrode layer 1123 in the display area storage capacitor area is connected to the switching element 120 through the grooves 1131.

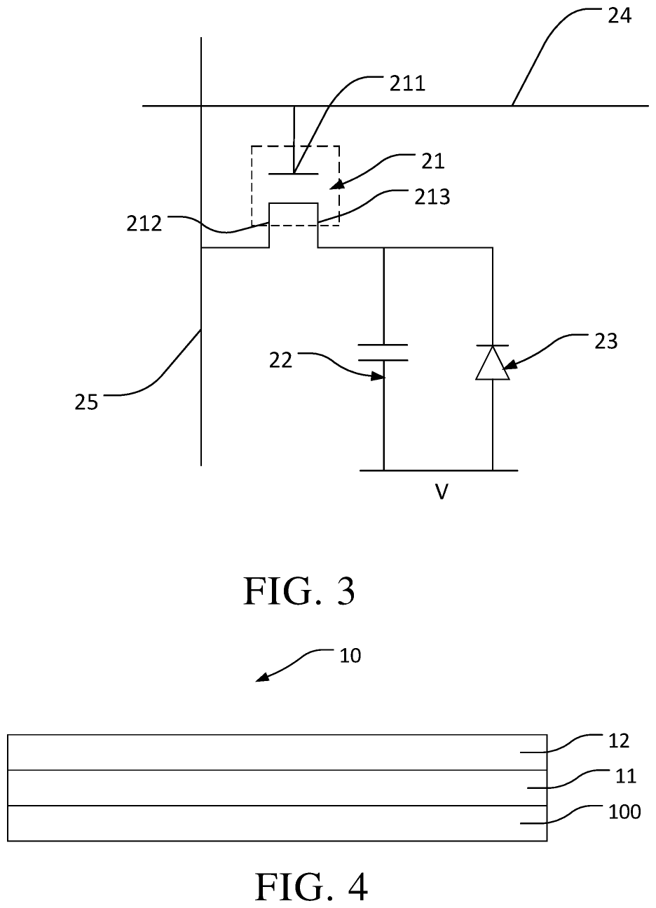

As shown in FIG. 3, FIG. 3 is an equivalent circuit diagram of the fingerprint identification element 130 in the array substrate 100 provided by the present disclosure, which is a 1T1C structure circuit. Specifically, it comprises a scanning line 24 disposed horizontally and a reading line 25 disposed vertically, a gate electrode 211 of a thin film transistor 21 is connected to the scanning line 24, a source electrode 212 of the thin film transistor 21 is connected to the reading line 25, and a drain electrode 213 of the thin film transistor 21 is connected to a parallel circuit. The parallel circuit comprises a storage capacitor 22 as a branch, a photodiode 23 is connected in series in another branch, and another end of the parallel circuit is connected to a diode biased voltage source V.

As shown in FIG. 4, an embodiment of the present disclosure further provides a display panel 10. The display panel 10 comprises the array substrate 100, a liquid crystal layer 11 and a color filter substrate 12.

The liquid crystal layer 11 is disposed on the array substrate 100, and the color filter substrate 12 is disposed on the liquid crystal layer 11.

The embodiments of the present disclosure provide the array substrate 100 and the display panel 10. Through horizontally disposing the switching element 120 and the fingerprint identification element 130 of the fingerprint identification component 160 in the thin film transistor layer 110, the fingerprint identification element 130 and the switching element 120 can be manufactured with the thin film transistor layer 110 at a same time, which can reduce a thickness of the panel, and a structure thereof is simple and not complicated. Specifically, when manufacturing the first semiconductor 1041 and the second semiconductor 1042, the doped regions can also be manufactured at a same time by introducing phosphine and borane gases after patterning corresponding patterns, so that an additional process for introducing gases is unnecessary, thereby saving cost.

In addition, compared to conventional LTPS processes, the present disclosure only needs to add masks for manufacturing the first P+ doped region 1042-2 and the photosensitive layer, thereby having lower production cost.

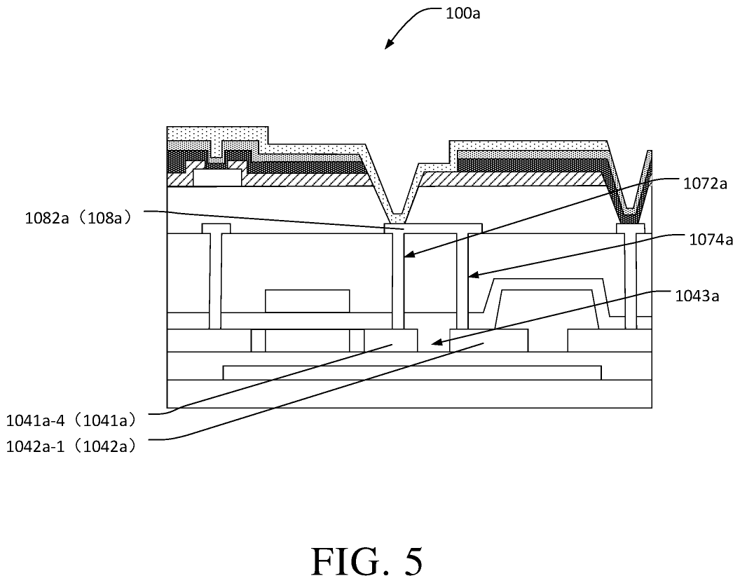

As shown in FIG. 5, differences of an array substrate 100a in another embodiment of the present disclosure from embodiment 1 are that there is a second gap 1043a defined between the first semiconductor 1041a and the second semiconductor 1042a, the first metal layer 108a has a connecting line 1082a, one end of the connecting line 1082a is connected to the first semiconductor 1041a, and another end of the connecting line 1082a is connected to the second semiconductor 1042a.

Specifically, the via holes further comprises a fourth via hole 1074a, the second metal line 1082a is connected to the second N+ doped region 1041a-4 through the second via hole 1072a, and another end of the second metal line 1082a is connected to the first N+ doped region 1042a-1 through the fourth via hole 1074a. Wherein, a metal line of the second metal line 1082a connected to the second N+ doped region 1041a-4 may act as the source electrode wire or the drain electrode wire of the first semiconductor 1041a.

It can be understood that for a person of ordinary skill in the art, equivalent replacements or changes can be made according to the technical solution of the present disclosure and its inventive concept, and all these changes or replacements should fall within the protection scope of the claims attached to the present disclosure.

1. An array substrate, comprising:
a substrate;
a thin film transistor layer disposed on the substrate; and
a fingerprint identification component disposed in the thin film transistor layer;
wherein the fingerprint identification component comprises a switching element and a fingerprint identification element, and the switching element and the fingerprint identification element are adjacently disposed on the substrate; and
the switching element comprises a first semiconductor, the fingerprint identification element comprises a second semiconductor, and the first semiconductor and the second semiconductor are manufactured on a same layer.

2. The array substrate according to claim 1, wherein the thin film transistor layer comprises:
a semiconductor layer disposed on the substrate, wherein the first semiconductor and the second semiconductor are disposed in the semiconductor layer;
a gate insulating layer disposed on the semiconductor layer;
a gate electrode disposed on the gate insulating layer and corresponding to the first semiconductor;
an interlayer insulating layer disposed on the gate insulating layer and the gate electrode;
a first metal layer disposed on the interlayer insulating layer and connected to the semiconductor layer by at least one via hole, wherein the via hole penetrates through the interlayer insulating layer and the gate insulating layer; and
a planarization layer disposed on the first metal layer and the interlayer insulating layer.

3. The array substrate according to claim 2, wherein the second semiconductor comprises a first N+ doped region and a first P+ doped region, and a first gap is defined between the first N+ doped region and the first P+ doped region; and
the first metal layer has a first metal line vertically connected to the first P+ doped region.

4. The array substrate according to claim 2, wherein the first metal layer has a second metal line, one end of the first semiconductor is directly connected to one end of the second semiconductor, and the first semiconductor and the second semiconductor are respectively connected to the second metal line.

5. The array substrate according to claim 2, wherein a second gap is defined between the first semiconductor and the second semiconductor; and
the first metal layer has a connecting line, one end of the connecting line is connected to the first semiconductor, and another end of the connecting line is connected to the second semiconductor.

6. The array substrate according to claim 3, wherein the second semiconductor further comprises a first active region disposed in the first gap.

7. The array substrate according to claim 6, further comprising: a photosensitive layer disposed on the second semiconductor and corresponding to the first gap or first active region, wherein a material of the photosensitive layer is amorphous silicon.

8. The array substrate according to claim 1, further comprising: an insulating layer disposed between the substrate and the thin film transistor layer;
a second metal layer disposed on the thin film transistor layer;
a touch control insulating layer disposed on a first electrode layer and provided with a slot recessed to a surface of the second first electrode layer; and
a storage capacitor layer disposed on the touch control insulating layer and in the slot, and connected to the first metal layer.

9. The array substrate according to claim 8, wherein the storage capacitor layer comprises:
a first transparent electrode layer disposed on the touch control insulating layer;
a passivation layer disposed on the first transparent electrode layer and the touch control insulating layer; and
a second transparent electrode layer disposed on the passivation layer.

10. A display panel, comprising the array substrate according to claim 1;
a liquid crystal layer disposed on the array substrate; and
a color filter substrate disposed on the liquid crystal layer.
